(19) United States
(12) Patent Application Publication
(10) Pub. No.: US 2012/0167936 A1
(43) Pub. Date: Jul. 5, 2012

(54) THERMOELECTRIC DEVICE BASED ON SILICON NANOWIRES AND MANUFACTURING METHOD THEREOF

(75) Inventors: Young Sam PARK, Daejeon (KR); Moon Gyu Jang, Daejeon (KR); Younghoon Hyun, Seoul (KR); Myungsim Jun, Daejeon (KR); Taehyoung Zyung, Daejeon (KR)

(73) Assignee: ELECTRONICS AND TELECOMMUNICATIONS RESEARCH INSTITUTE, Daejeon (KR)

(21) Appl. No.: 13/325,082

(22) Filed: Dec. 14, 2011

(30) Foreign Application Priority Data
Dec. 30, 2010 (KR) 10-2010-0139451

(51) Int. Cl. H01L 35/32; H01L 21/02; B82Y 40/00; B82Y 99/00; H01L 35/34

(52) U.S. Cl. 136/205; 438/54; 136/201; 977/948; 977/762

(57) ABSTRACT

Disclosed are a thermoelectric device based on silicon nanowires including: a substrate; a silicon heat absorbing part absorbing heat, a silicon nanowire leg transferring heat, and a silicon heat releasing part releasing heat, which are formed on the substrate; and an insulating film with at least one or more holes, which is formed on the substrate including the silicon heat absorbing part, the silicon nanowire leg, and the silicon heat releasing part, and a method for manufacturing the same.

### CROSS-REFERENCE TO RELATED APPLICATIONS

This application is based on and claims priority from Korean Patent Application No. 10-2010-0139451, filed on Dec. 30, 2010, with the Korean Intellectual Property Office, the disclosure of which is incorporated herein in its entirety by reference.

### TECHNICAL FIELD

The present disclosure relates to a thermoelectric device capable of converting heat energy into electric energy, and more particularly, to a thermoelectric device based on silicon nanowires, which can be manufactured using a semiconductor process and has a low thermal loss, and a method for manufacturing the same.

### BACKGROUND

At present, most energy source has been obtained from fossil fuel all over the world. However, the rapid growth of Chinese and Indian economies and growth in the global population cause the risk of fossil fuel exhaustion. In addition, the use of fossil fuel causes climate change, such as sweltering heat and flood, as well as global warming and environmental pollution.

To solve global warming and environmental pollution problems, climate change convention and CO₂ regulation are now enforced throughout the world, and this has also caused a great change in automobile and energy industries.

To solve fossil fuel exhaustion problems, the development of new clean energy causing no environmental pollution has been spurred. As one example, a thermoelectric device is a device that converts heat energy into electric energy. A thermoelectric device is one of the representative technical fields that can simultaneously meet the recent energy and eco-friendly policies. As a heat source of a thermoelectric device, all heat existing on the earth, for example, solar heat, waste heat from vehicle, geothermal heat, body heat, or radioactive heat, may be used as energy source for the thermoelectric device.

A thermoelectric effect was first discovered in 1800's by Thomas Seebeck. Thomas Seebeck connected bismuth and copper and disposed a compass therein. When one side of the bismuth was heated to high temperature, a current was induced due to a temperature difference. A magnetic field created by the induced current moved a needle of the compass. From this, Thomas Seebeck first observed a thermoelectric effect.

A value of Figure of Merit (ZT) is used as an index of thermoelectric efficiency. The ZT value is proportional to electric conductivity and the square of a Seebeck coefficient, and is inversely proportional to thermal conductivity. These terms are greatly dependent on inherent characteristics of a material. Metal has a very low Seebeck coefficient of several uV/K, and its electric conductivity is proportional to its thermal conductivity according to Wiedemann-Franz law. Thus, metal has a limitation in increasing the ZT value.

Meanwhile, scientists have conducted consistent research into semiconductor materials, and thermoelectric devices using body heat and radioactive heat as a heat source thereof are now on the market. However, the market for thermoelectric devices is still small. As a material for a launched thermoelectric device, Bi₂Te₃-based materials are unique. Bi₂Te₃ has a ZT value of 0.7 at room temperature and has the maximum ZT value of 0.9 at 120. Bi₂Te₃-based materials are adopted and used for bulk-based thermoelectric devices.

Much attention has been recently paid to research based on silicon, which is a basic material in the semiconductor industry. The reserves of the existing Bi₂Te₃-based materials are limited and the Bi₂Te₃-based materials are classified as carcinogen. Since the Bi₂Te₃-based material in itself is easily broken, it is difficult to process and its manufacturing cost is high. On the other hand, the reserves of silicon are infinite and the material in itself is nontoxic. In addition, silicon is easy to process and its manufacturing cost is low.

However, silicon has very high thermal conductivity of 150 W/m·K and has a ZT value of 0.01, so it has been recognized as being difficult to be used for thermoelectric devices. In recent years, however, silicon nanowires grown by Chemical Vapor Deposition (CVD) can reduce thermal conductivity to 0.01 times or less, and thus, their ZT value approaches 1. Two papers were reported in the journal Nature in 2008: [Allon I. Hochbaum, Renkun Chen, Raul Diaz Delgado, Wenjie Liang, Erik C. Garnett, Mark Najarian, Arun Majumdar and Peidong Yang, Nature, vol. 451 (2008) p. 163][Akram I. Boukai, Yuri Bunimovich, Jamil Tahir-Kheli, Jen-Kan Yu, William A. Goddard III and James R. Heath, Nature, vol. 451 (2008) p. 168].

Since then, explosive attention has been paid to the research on thermoelectric devices based on nanowires. However, in the case of the existing technique reported in the journal Nature, silicon nanowires are separately grown and then adhered to a heat absorbing part and a heat releasing part hanging on the air. Therefore, thermoelectric devices based on nanowires have great difficulty in integration and commercialization. One of the greatest reasons for this may be the absence of a method for manufacturing nanowires in mass production. Most manufacturing methods separately grow silicon nanowires within a furnace using a catalyst or non-catalyst method. However, such a separate growing method has two limitations. First, nanowires are not grown consistently in a single direction, and some nanowires are grown in an undesired direction and hinder the growth of other nanowires. Thus, the separate growing method has a great limitation in acquiring high-quality nanowires. Second, nanowires separately grown within a furnace are moved to a device and are adhered thereto in use. That is, since the nanowires are not formed integrally with the device, mass production is difficult and the adhering process is time-consuming, leading to considerable increase of costs.

To solve this limitation, ETRI proposed a thermoelectric device based on silicon nanowires, to which a Complementary Metal Oxide Semiconductor (CMOS) based top-down fabricating method was applied. [Korean Patent Application No (Filing date): 2008-0118110 (Nov. 26, 2008), 2010-0088107 (Sep. 8, 2010) and 2010-0011284 (Feb. 8, 2010)]

A thermoelectric device based on top-down fabricated silicon nanowires generally has a leg diameter of several nm. Therefore, in an entire heat flow from the heat absorbing part to the leg and from the leg to the heat releasing part, a heat flow through the leg may occupy a slight portion. If the heat flow through the leg occupies a slight portion, the heat absorbing part and the heat releasing part quickly reach thermal equilibrium, and characteristics of movement of carriers through the leg are degraded. That is, the thermoelectric efficiency of the thermoelectric device capable of converting heat energy into electric energy is greatly reduced.

### SUMMARY

The present disclosure has been made in an effort to provide a thermoelectric device based on silicon nanowires with low thermal loss.

The present disclosure has been made in another effort to provide a method for manufacturing a thermoelectric device based on silicon nanowires, in which a silicon nanowire leg, a silicon heat absorbing part, and a silicon heat releasing part can be integrally formed.

An exemplary embodiment of the present disclosure provides a thermoelectric device based on silicon nanowires, including: a substrate; a silicon heat absorbing part absorbing heat, a silicon nanowire leg transferring heat, and a silicon heat releasing part releasing heat, which are formed on the substrate; and an insulating film with at least one or more holes, which is formed on the substrate including the silicon heat absorbing part, the silicon nanowire leg, and the silicon heat releasing part.

Another exemplary embodiment of the present disclosure provides a method for manufacturing a thermoelectric device based on silicon nanowires, including: sequentially forming an oxide film and a silicon thin film on a substrate; designating a conductivity type, N type or P type, to a region of the silicon thin film to be patterned into a silicon nanowire leg; patterning the silicon thin film to form a structure defining a silicon heat absorbing part absorbing heat, a silicon nanowire leg transferring heat, and a silicon heat releasing part releasing heat; forming an insulating film with at least one or more holes by depositing an insulating thin film on the oxide film which includes the silicon heat absorbing part, the silicon nanowire leg, and the silicon heat releasing part, and patterning the deposited insulating thin film; and removing the oxide film by an etching process using the at least one or more holes.

Yet another exemplary embodiment of the present disclosure provides a thermoelectric device based on silicon nanowires, including: a substrate; and a silicon heat absorbing part absorbing heat and including at least one or more holes, a silicon nanowire leg transferring heat, and a silicon heat releasing part releasing heat, which are formed on the substrate.

Still another exemplary embodiment of the present disclosure provides a method for manufacturing a thermoelectric device based on silicon nanowires, including: sequentially forming an oxide film and a silicon thin film on a substrate; designating a conductivity type, N type or P type, to a region of the silicon thin film to be patterned into a silicon nanowire leg; patterning the silicon thin film to form a structure defining a silicon heat absorbing part absorbing heat and including at least one or more holes, a silicon nanowire leg transferring heat, and a silicon heat releasing part releasing heat; and removing the oxide film by an etching process using the at least one or more holes.

According to the exemplary embodiments of the present disclosure, there are provided a thermoelectric device based on silicon nanowires, in which bottoms of a silicon nanowire leg, a silicon heat absorbing part, and a silicon heat releasing part are surrounded by air, and a manufacturing method thereof. Therefore, heat loss is low, and the silicon nanowire leg, the silicon heat absorbing part, and the silicon heat releasing part can be integrally formed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A to 1G are a process flowchart explaining a method for manufacturing a thermoelectric device based on silicon nanowires according to an exemplary embodiment of the present disclosure.

FIGS. 2A to 2F are a process flowchart explaining a method for manufacturing a thermoelectric device based on silicon nanowires according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

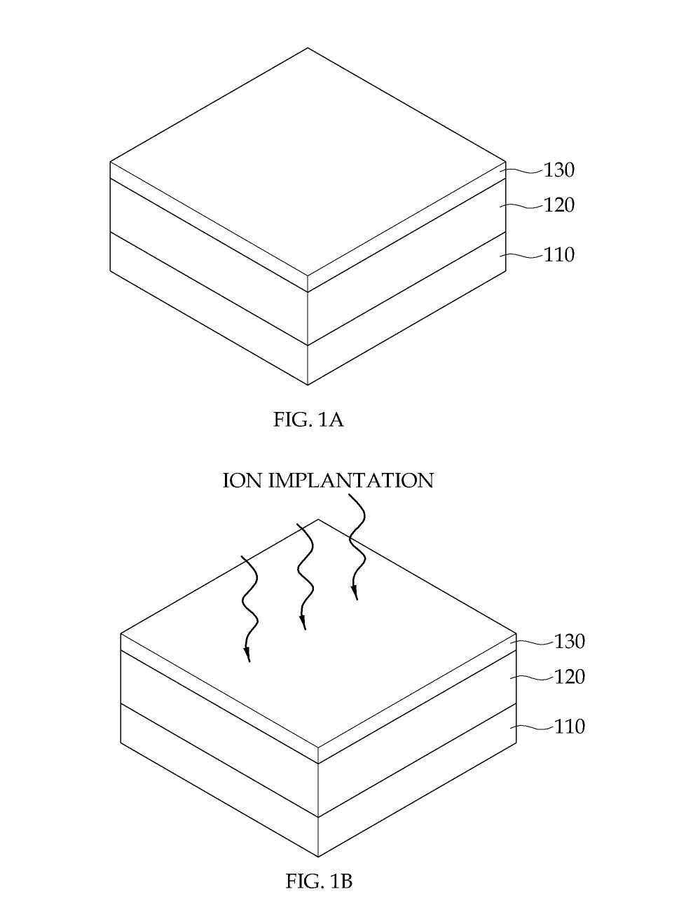

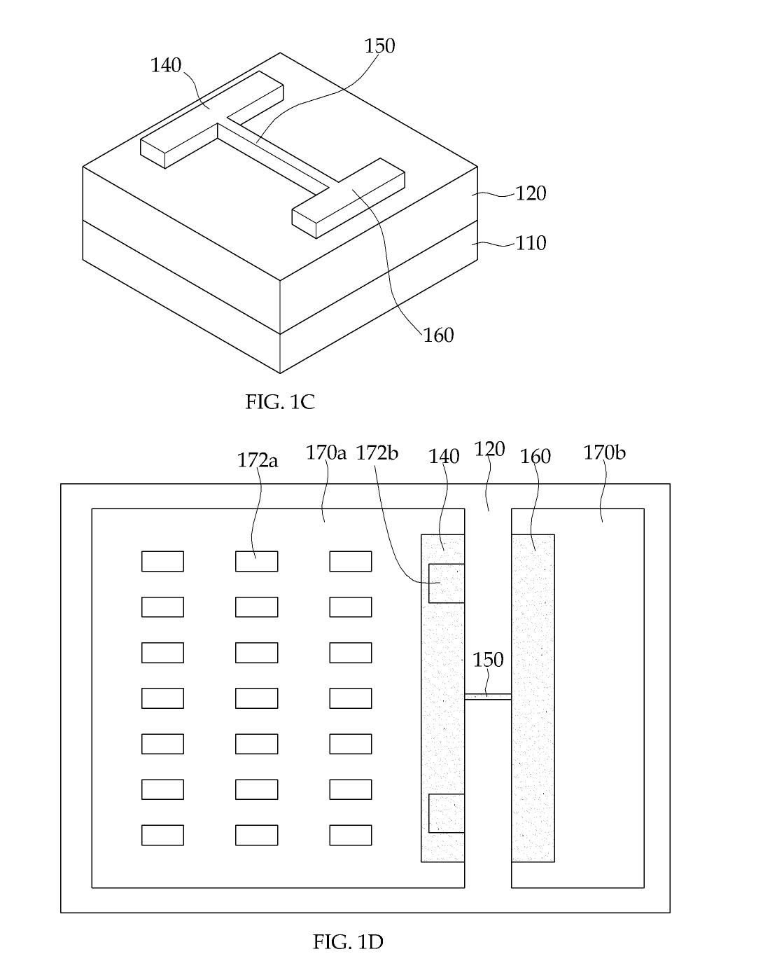

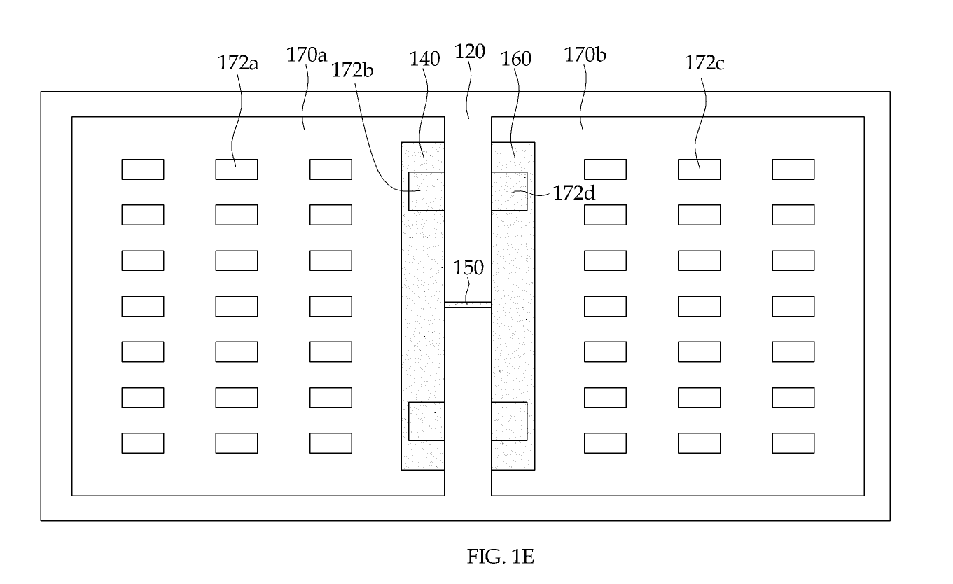

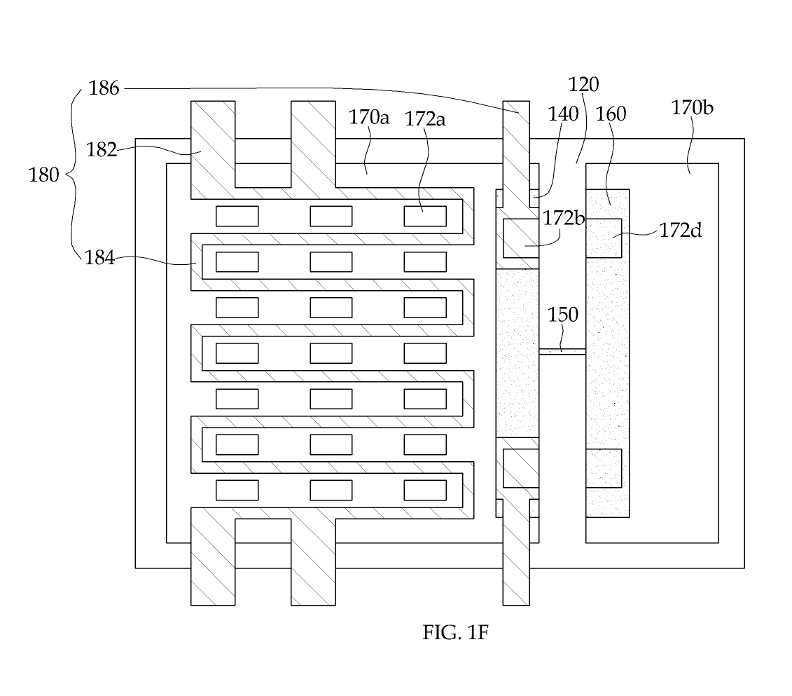

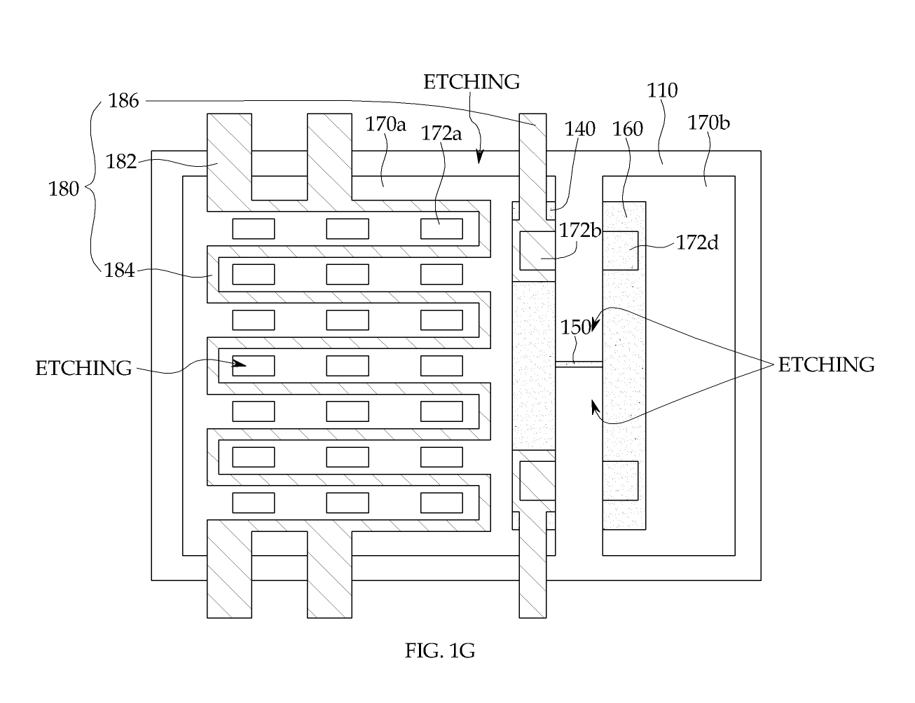

FIGS. 1A to 1G are a process flowchart explaining a method for manufacturing a thermoelectric device based on silicon nanowires according to an exemplary embodiment of the present disclosure.

Referring to FIG. 1A, an oxide film 120 and a silicon thin film 130 are sequentially formed on a substrate 110. Substrate 110 may be a silicon substrate or a silicon on insulator (SOI) substrate.

In the case where the silicon substrate is used as substrate 110, oxide film 120 is formed on substrate 110 and then silicon thin film 130 is formed to a thickness of 10 nm to 500 nm.

In the case where the SOI substrate is used as substrate 110, an oxide film inside the SOI substrate is used instead of oxide film 120, and silicon thin film 130 is formed to a thickness of 10 nm to 500 nm. At this time, when the thickness of silicon thin film 130 is several um or more, the thickness of silicon thin film 130 is reduced by repetitively performing a thermal oxidation process and a buffered oxide etchant (BOE) solution dipping process.

Referring to FIG. 1B, a conductivity type, N type or P type, is designated to a region of silicon thin film 130 to be patterned into a silicon nanowire leg 150 that will be described below. At this time, an ion implantation process is used to designate the conductivity type, N type or P type to the region to be patterned into silicon nanowire leg 150.

Referring to FIG. 1C, silicon thin film 130 is patterned to define a silicon heat absorbing part 140 absorbing heat, silicon nanowire leg 150 transferring heat, and a silicon heat releasing part 160 releasing heat. To implement silicon nanowire leg 150 having a line width of 10 nm to 500 nm, a semiconductor exposure process and a subsequent etching process may be used and an oxygen ashing process may be further used.

Referring to FIG. 1D, an insulating film is deposited on oxide film 120, which includes silicon heat absorbing part 140, silicon nanowire leg 150, and silicon heat releasing part 160, and is patterned to form insulating films 170a and 170b including at least one or more holes 172a and 172b. Insulating films 170a and 170b may be nitride films, and the thickness of insulating films 170a and 170b may range from 10 nm to 1 um. Therefore, insulating films 170a and 170b are not removed in a subsequent etching process for removing oxide film 120.

First hole 172a among at least one or more holes 172a and 172b formed in insulating films 170a and 170b enables an etching solution to flow along first hole 172a in a subsequent etching process, such that oxide film 120 under insulating film 170a may be removed. In addition, second hole 172b enables electrical connection between silicon heat absorbing part 140 and a metal interconnection 186 that will be described later.

Meanwhile, in FIG. 1D, at least one or more holes 172a and 172b are formed only in insulating film 170a contacting silicon heat absorbing part 140; however, the present disclosure is not limited thereto. As illustrated in FIG. 1E, at least one or more holes 172c and 172d may be formed even in insulating film 170b contacting silicon heat releasing part 160, as well as insulating film 170a contacting silicon heat absorbing part 140. First hole 172c among at least one or more holes 172c and 172d formed in insulating film 170b contacting silicon heat releasing part 160 enables an etching solution to flow along first hole 172c in a subsequent etching process, such that oxide film 120 under insulating film 170b may be removed. In addition, second hole 172d enables electrical connection between silicon heat releasing part 160 and a metal interconnection (not shown).

Referring to FIG. 1F, a metal interconnection 180 is formed on insulating film 170a contacting silicon heat absorbing part 140. Metal interconnection 180 may include any one element selected from Pt, Al, Cu, W, and Ti.

In the case where heat energy is supplied through a pad part 182 of metal interconnection 180, the heat energy is transferred to a coil part 184 of metal interconnection 180. The heat energy transferred to coil part 184 is transferred to silicon heat releasing part 160 via silicon heat absorbing part 140 and silicon nanowire leg 150.

In the case where electric energy is supplied through pad part 182 of metal interconnection 180, the electric energy is transferred to coil part 184 of metal interconnection 180. In coil part 184, heat energy is generated by joule heating, and the generated heat energy is transferred to silicon heat releasing part 160 via silicon heat absorbing part 140 and silicon nanowire leg 150.

Referring to FIG. 1G, oxide film 120 under insulating film 170a is removed using at least one or more holes 172a included in insulating film 170a.

Therefore, in the exemplary embodiment of the present disclosure, oxide film 120 under insulating films 170a and 170b can be effectively removed in a short time using at least one or more holes 172a and 172c included in insulating films 170a and 170b, and the bottoms of insulating films 170a and 170b contact air, further suppressing heat loss of the thermoelectric device.

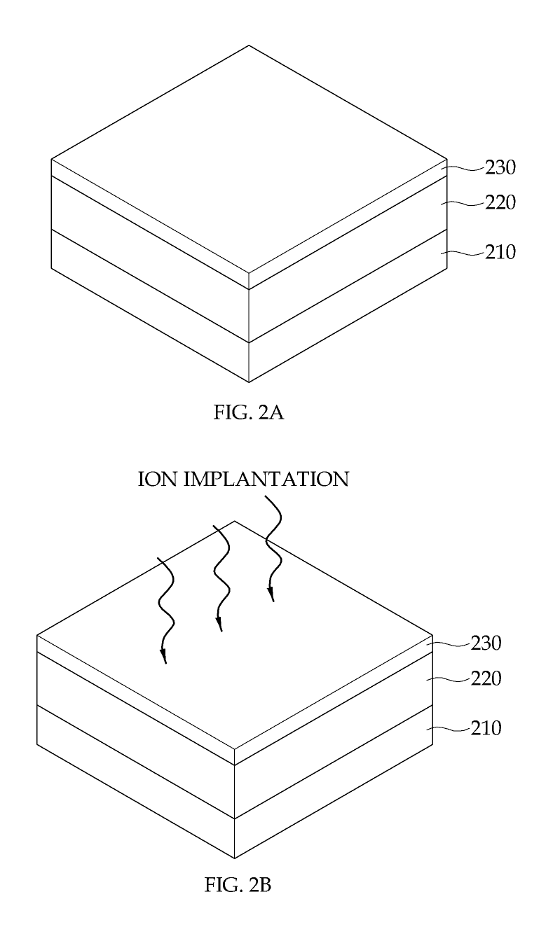

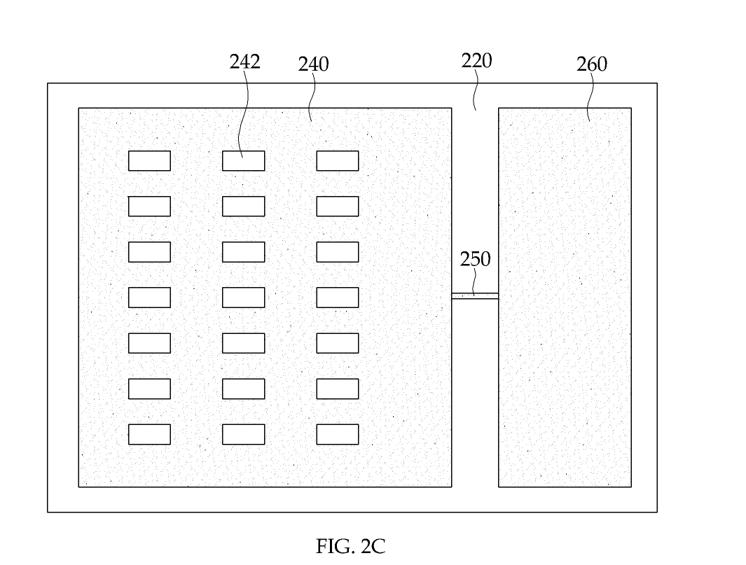

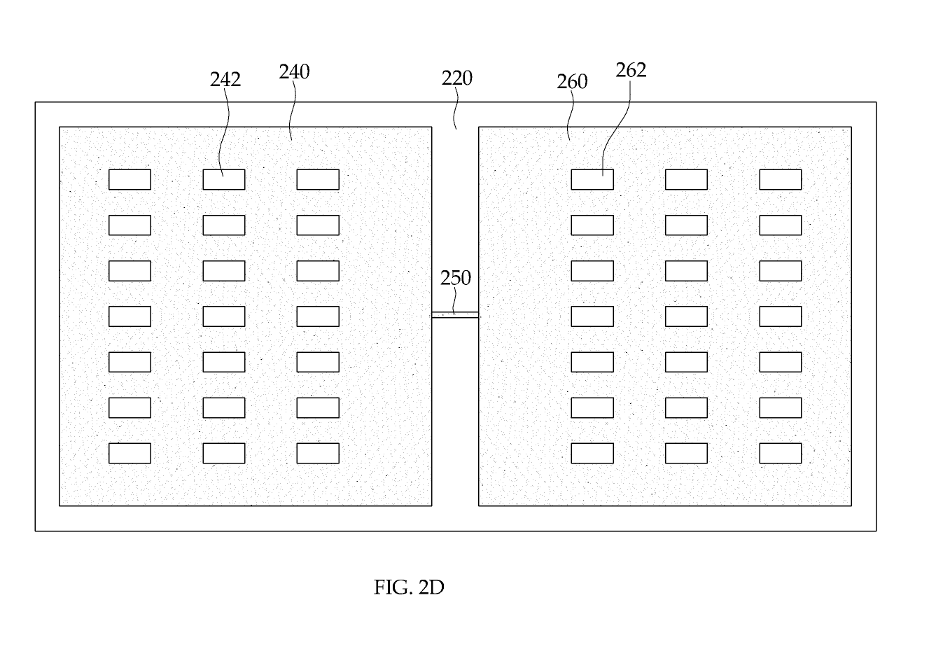

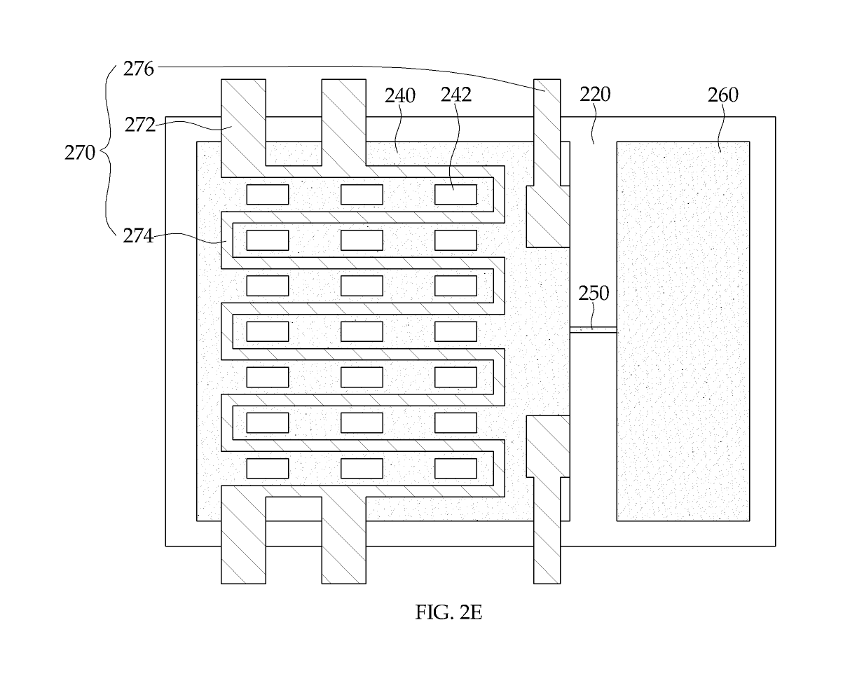

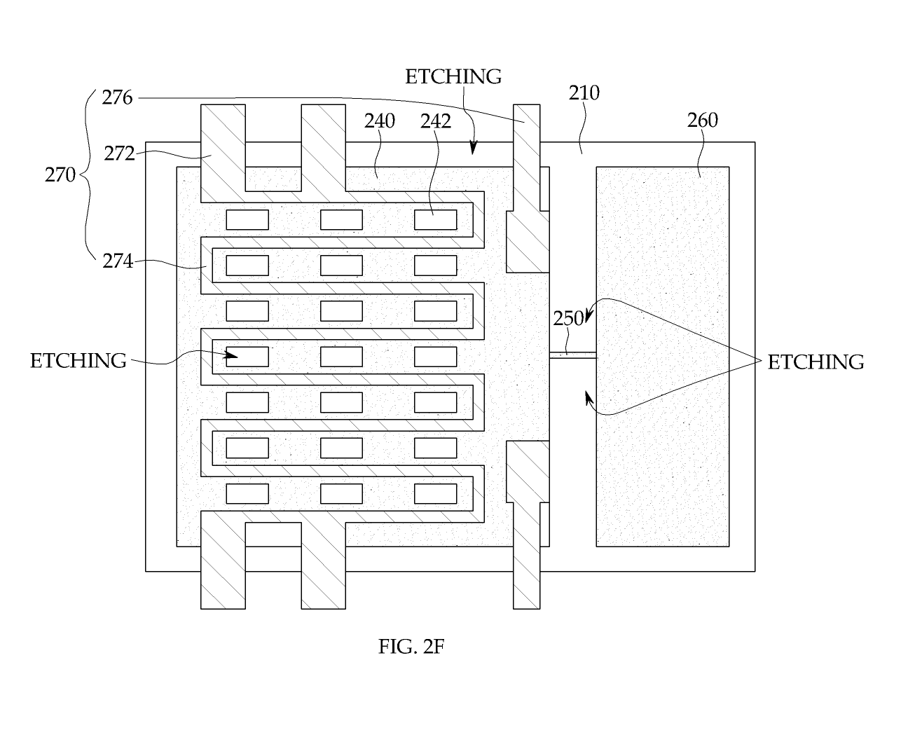

FIGS. 2A to 2F are a process flowchart explaining a method for manufacturing a thermoelectric device based on silicon nanowires according to another exemplary embodiment of the present disclosure.

In FIGS. 2A and 2B, since a process of sequentially forming an oxide film 220 and a silicon thin film 230 on a substrate 210 and designating a conductivity type, N type or P type, to a region of silicon thin film 230 to be patterned into a silicon nanowire leg 250 that will be described below is the same as the process of FIGS. 1A and 1B, the detailed description thereof will be omitted.

Referring to FIG. 2C, silicon thin film 230 is patterned to define a silicon heat absorbing part 240 absorbing heat, silicon nanowire leg 250 transferring heat, and a silicon heat releasing part 260 releasing heat. At least one or more holes 242 are formed in silicon heat absorbing part 240.

At least one or more holes 242 formed in silicon heat absorbing part 240 make it easy to remove oxide film 220 under silicon heat absorbing part 240 in a subsequent etching process.

Meanwhile, in FIG. 2C, at least one or more holes 242 are formed only in silicon heat absorbing part 240; however, the present disclosure is not limited thereto. As illustrated in FIG. 2D, at least one or more holes 262 may be formed even in silicon heat releasing part 260, as well as silicon heat absorbing part 240. At least one or more holes 262 formed in silicon heat releasing part 260 make it easy to remove oxide film 220 under silicon heat releasing part 260 in an etching process.

Referring to FIG. 2E, a metal interconnection 270 is formed on silicon heat absorbing part 240. Metal interconnection 270 may include any one element selected from Pt, Al, Cu, W, and Ti.

In the case where heat energy is supplied through a pad part 272 of metal interconnection 270, the heat energy is transferred to a coil part 274 of metal interconnection 270. The heat energy transferred to coil part 274 is transferred to silicon heat releasing part 260 via silicon heat absorbing part 240 and silicon nanowire leg 250.

In the case where electric energy is supplied through pad part 272 of metal interconnection 270, the electric energy is transferred to coil part 274 of metal interconnection 270. In coil part 274, heat energy is generated by joule heating, and the generated heat energy is transferred to silicon heat releasing part 260 via silicon heat absorbing part 240 and silicon nanowire leg 250.

Referring to FIG. 2F, oxide film 220 under silicon heat absorbing part 240 is removed using at least one or more holes 242 included in silicon heat absorbing part 240.

Therefore, in another exemplary embodiment of the present disclosure, oxide film 220 under silicon heat absorbing part 240 can be effectively removed in a short time using at least one or more holes 242 included in silicon heat absorbing part 240, and the bottom of silicon heat absorbing part 240 contacts air, further suppressing heat loss of the thermoelectric device.

As illustrated in FIG. 2D, in the case where at least one or more holes 242 and 262 are formed in silicon heat absorbing part 240 and silicon heat releasing part 260, oxide films 220 under silicon heat absorbing part 240 and silicon heat releasing part 260 can be removed at the same time, and the bottoms of silicon heat absorbing part 240 and silicon heat releasing part 260 contact air, further suppressing heat loss of the thermoelectric device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A thermoelectric device based on silicon nanowires, comprising:
a substrate;
a silicon heat absorbing part absorbing heat, a silicon nanowire leg transferring heat, and a silicon heat releasing part releasing heat, which are formed on the substrate; and
an insulating film with at least one or more holes, which is formed on the substrate including the silicon heat absorbing part, the silicon nanowire leg, and the silicon heat releasing part.

2. The thermoelectric device of claim 1, wherein the silicon nanowire leg has a line width ranging from 10 nm to 500 nm.

3. The thermoelectric device of claim 1, wherein the silicon heat absorbing part, the silicon nanowire leg, and the silicon heat releasing part have a thickness ranging from 10 nm to 500 nm.

4. The thermoelectric device of claim 1, wherein the insulating film is a nitride film.

5. The thermoelectric device of claim 1, wherein the insulating film has a thickness ranging from 10 nm to 1 um.

6. The thermoelectric device of claim 1, further comprising a metal interconnection formed on the insulating film.

7. The thermoelectric device of claim 6, wherein the metal interconnection includes at least one selected from Pt, Al, Cu, W, and Ti.

8. The thermoelectric device of claim 1, wherein the insulating film contacts the silicon heat absorbing part.

9. The thermoelectric device of claim 1, wherein the insulating film includes:
a first insulating film contacting the silicon heat absorbing part; and
a second insulating film contacting the silicon heat releasing part.

10. A method for manufacturing a thermoelectric device based on silicon nanowires, the method comprising:
sequentially forming an oxide film and a silicon thin film on a substrate;
designating a conductivity type, N type or P type, to a region of the silicon thin film to be patterned into a silicon nanowire leg;
patterning the silicon thin film to form a structure defining a silicon heat absorbing part absorbing heat, a silicon nanowire leg transferring heat, and a silicon heat releasing part releasing heat;
forming an insulating film with at least one or more holes by depositing an insulating thin film on the oxide film which includes the silicon heat absorbing part, the silicon nanowire leg, and the silicon heat releasing part, and patterning the deposited insulating thin film; and
removing the oxide film by an etching process using the at least one or more holes.

11. The method of claim 10, further comprising forming a metal interconnection on the insulating film.

12. A thermoelectric device based on silicon nanowires, comprising:
a substrate; and
a silicon heat absorbing part absorbing heat and including at least one or more holes, a silicon nanowire leg transferring heat, and a silicon heat releasing part releasing heat, which are formed on the substrate.

13. The thermoelectric device of claim 12, wherein the silicon nanowire leg has a line width ranging from 10 nm to 500 nm.

14. The thermoelectric device of claim 12, wherein the silicon heat absorbing part, the silicon nanowire leg, and the silicon heat releasing part have a thickness ranging from 10 nm to 500 nm.

15. The thermoelectric device of claim 12, further comprising a metal interconnection formed on the silicon heat absorbing part.

16. The thermoelectric device of claim 15, wherein the metal interconnection includes at least one selected from Pt, Al, Cu, W, and Ti.

17. The thermoelectric device of claim 12, wherein the silicon heat releasing part includes at least one or more holes.

18. A method for manufacturing a thermoelectric device based on silicon nanowires, the method comprising:
sequentially forming an oxide film and a silicon thin film on a substrate;
designating a conductivity type, N type or P type, to a region of the silicon thin film to be patterned into a silicon nanowire leg;
patterning the silicon thin film to form a structure defining a silicon heat absorbing part absorbing heat and including at least one or more holes, a silicon nanowire leg transferring heat, and a silicon heat releasing part releasing heat; and
removing the oxide film by an etching process using the at least one or more holes.

19. The method of claim 18, wherein, in forming the structure, at least one or more holes are formed in the silicon heat releasing part.
